(19) United States
(12) Patent Application Publication
(10) Pub. No.: US 2003/0003696 A1
(43) Pub. Date: Jan. 2, 2003

(54) Method and apparatus for tuning a plurality of processing chambers

(76) Inventors: Avgerinos Gelatos, Redwood City, CA (US); Joel M. Huston, San Jose, CA (US); Lawrence Chung-Lai Lei, Milipitas, CA (US); Vicky Uyen Nguyen, San Jose, CA (US); Yin Lin, Palo Alto, CA (US); Fong Chang, Los Gatos, CA (US)

Correspondence Address: APPLIED MATERIALS, INC., 2881 SCOTT BLVD. M/S 2061, SANTA CLARA, CA, 95050, US

(21) Appl. No.: 09/896,124

(22) Filed: Jun. 29, 2001

(51) Int. Cl. H01L 21/36; H01L 21/20; C30B 1/00

(52) U.S. Cl. 438/485; 438/507; 438/935

(57) ABSTRACT

Generally, a substrate processing apparatus is provided. In one aspect of the invention, a substrate processing apparatus is provided. In one embodiment, the substrate processing apparatus includes one or more chamber bodies coupled to a gas distribution system. The chamber bodies define at least a first processing region and a second processing region within the chamber bodies. The gas distribution system includes a first, a second and a third gas supply circuit. The first gas supply circuit is teed between the first and second processing regions and is adapted to supply a first processing gas thereto. The second gas supply circuit is coupled to the first processing region and adapted to supply a second process gas thereto. The third gas supply circuit is coupled to the second processing region and is adapted to supply a third process gas thereto. Alternatively, the processing regions may be disposed in a single chamber body.

### BACKGROUND OF THE INVENTION

1. Field of the Invention

Embodiments of the invention relate to a method and apparatus for performing chemical vapor deposition.

2. Background of the Related Art

Chemical vapor deposition, or CVD, is a well-known and practiced technique for the deposition of material on a substrate such as a semiconductor wafer. A CVD chamber is typically defined by electrically grounded walls and a lid. A pedestal for supporting the substrate is disposed within the chamber. A showerhead is disposed beneath the lid and above the pedestal. Coupled to the chamber is a gas panel and optionally an RF power source. The gas panel is coupled to the showerhead and provides process and other gases to the chamber. The process gases and the substrate are pre-heated to a temperature that facilitates thermal decomposition of the gases and substrate film formation. In plasma enhanced systems, the showerhead is coupled to an RF source. When used, the RF source drives the showerhead, igniting and sustaining a process gas plasma that enhances the deposition process for plasma-enhanced CVD (PECVD). Deposition occurs when the process gas or gases injected into the chamber react to form a layer of material on the substrate.

One particular type of CVD processing system comprises a chamber having an internal wall that bifurcates the chamber into two separate processing regions. Generally, the process gases are supplied to the process regions via a single gas panel. This configuration has generally provided robust processing performance and enhanced throughput over conventional CVD chamber designs. Occasionally, under certain process conditions, the substrates processed in each processing region may not yield matching deposition results. As substrate to substrate deposition uniformity is highly desirable, the ability to tune the deposition results between the process regions is highly desirable. Therefore, a need exists in the art for a method and apparatus for tuning a CVD process in twin chamber designs.

### SUMMARY OF THE INVENTION

In one embodiment, a substrate processing apparatus is provided which includes one or more chamber bodies coupled to a gas distribution system. The chamber bodies define at least a first processing region and a second processing region therein. The gas distribution system includes a first, a second and a third gas supply circuit. The first gas supply circuit is coupled between the first and second processing regions and is adapted to supply a first processing gas thereto. The second gas supply circuit is coupled to the first processing region and adapted to supply a second process gas thereto. The third gas supply circuit is coupled to the second processing region and is adapted to supply a third process gas thereto.

In another embodiment, the substrate processing apparatus includes a chamber body coupled to a gas distribution circuit. The chamber body includes a top, a bottom and sidewalls. At least one interior wall is coupled between the top and bottom and defines at least a first processing region and a second processing region within the chamber body. The gas distribution system includes a first, a second and a third gas supply circuit. The first gas supply circuit is coupled between the first processing region and the second processing region. The first gas supply has a flow controller adapted to selectively supply a first process gas or another process gas to the first and second processing regions. The second gas supply circuit is coupled to the first processing region and has a second flow controller adapted to supply a second process gas to the first processing region at a first rate. The third gas supply circuit is coupled to the second processing region and has a third flow controller adapted to supply a third process gas to the second processing region at a second rate. The first and second rates are independently controlled to tune deposition results between the first and second processing region.

In another aspect of the invention, a method for processing a plurality of substrates is provided. In one embodiment, the method includes flowing a first process gas to a first process region and a second process region through a common conduit coupled therebetween, flowing a second process gas to the first process region at a first rate, and flowing a third process gas to the second process region at a second rate, wherein the first rate and the second rate are independently controlled to tune processing results between the first process region and the second process region.

### BRIEF DESCRIPTION OF THE DRAWINGS

So that the manner in which the above-recited features, advantages and objects of the present invention are attained can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts a substrate processing system having a gas distribution system coupled to multiple processing regions; and

FIG. 2 depicts one embodiment of a gas distribution system.

To facilitate understanding, identical reference numerals have been used, wherever possible, to designate identical elements that are common to the figures.

### DETAILED DESCRIPTION OF THE PREFERRED EMBODIMENT

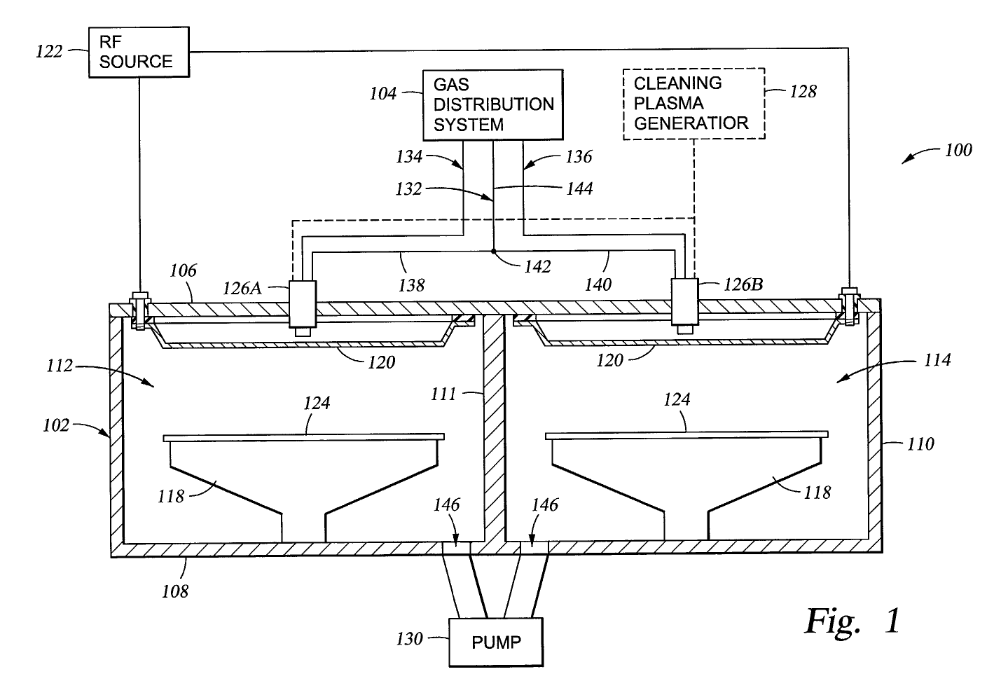

FIG. 1 depicts a substrate processing system 100 that includes a gas distribution system 104 coupled to a chamber body 102 having two or more substrate processing regions. Although the system 100 is described as a chemical vapor deposition (CVD) system, the invention has utility with other processing chamber such as physical vapor deposition (PVD) systems, etch systems and other processing systems having multiple processing regions defined within a chamber body. In addition, aspects of the invention have utility with single wafer processing system (as described below) and batch-type processing systems.

The chamber body 102 generally comprises a top 106, a bottom 108 and sidewalls 110. At least one interior wall 111 is disposed between the top 106 and bottom 108 of the chamber body 102 and defines at least a first processing region 112 and a second processing region 114. Although the processing regions 112, 114 are depicted as integral to a single chamber body 102, the regions 112, 114 (and other processing regions) may alternatively be disposed in a plurality of individual chambers or a single chamber with dividing walls.

Each processing region 112 and 114 generally includes a pedestal 118 disposed therein which is typically coupled to the chamber bottom 108 or the sidewalls 110. The pedestal 118 generally supports a substrate 124 during processing. The pedestal 118 may retain the substrate by a variety of methods including the use of an electrostatic chuck, vacuum clamps, mechanical clamps, gravity or other holding methods generally used to retain a substrate during processing.

Exhaust ports 146 typically couple the processing regions 112, 114 to a vacuum pump 130. Typically, the exhaust ports 146 are disposed in the bottom 108 of the chamber body 102, but may be located in other portions of the chamber body 102. A throttle valve (not shown) is generally disposed between the pump 130 and each exhaust port 146 and is utilized to regulate pressure in the processing regions 112, 114. Optionally, each exhaust port 146 may be coupled to a dedicated pump.

A showerhead 120 is generally coupled to the top 106 of the chamber body 102 above the pedestal 118. The showerhead 120 generally includes a plurality of holes formed in a center portion of the showerhead 120 that uniformly distribute process and other gases to the processing regions 112, 114.

Gas boxes 126A, 126B are generally disposed in the top 106 of the chamber body 102 and fluidly couple each processing regions 112, 114, respectively, to the gas distribution system 104. The gas boxes 126A, 126B generally mix the process and/or other gases delivered from the gas distribution system 104 and injects the mixed (or partially mixed) gases into an area defined between the showerhead 120 and the top 106 of the chamber body 102. The mixed gases then flow through the showerhead 120 into the processing regions 112, 114. A gas box that may be adapted to benefit from the invention is described in U.S. patent application Ser. No. 09/609,994, filed Jul. 5, 2000 by Shmurun et al., which is hereby incorporated by reference in its entirety.

A cleaning plasma generator 128 may also be coupled to the processing regions 112, 114 through the gas boxes 126A, 126B. In one embodiment, the cleaning plasma generator 128 provides a cleaning agent such as atomic fluorine which removes unwanted deposition and other contaminants from the chamber components. One such generator is available from Azte Corporation.

Optionally, a RF power source 122 may be coupled to the showerhead 120. The RF power source 122 drives the showerhead 120, igniting and sustaining a plasma of the mixed process gas(es) and/or other gases within the respective processing regions 112, 114. Plasma enhanced processing enables processing within the processing regions 112, 114 to operate at lower temperatures, provides additional process flexibility and provides a capability for the system 100 to be used for varied types of deposition processes.

The gas distribution system 104 generally includes at least a first gas supply circuit 132, a second gas supply circuit 134 and a third gas supply circuit 136. The first gas supply circuit 132 generally couples one or more gas sources to a main supply line 144 providing at least a first process gas. The main supply line 144 is coupled by a tee 142 to a first chamber branch line 138 and a second chamber branch line 140. The first chamber branch line 138 is fluidly coupled to the first gas box 126A while the second chamber branch line 140 is fluidly coupled to the second gas box 126B. The branch lines 138, 140 may be at least partially routed through the top 106 or walls 110 of the chamber body 102 to thermally condition the gases before mixing and delivery into the processing regions 112, 114.

The second gas supply circuit 134 is generally coupled to the first gas box 126A and provides a second process gas thereto. The third gas supply circuit 136 is generally coupled to the second gas box 126B and provides a third process gas thereto. Typically, although not limited thereto, the second and third process gases are the same whether from independent or common sources. As with the branch lines 138, 140, at least a portion of the circuits 134 may be at least partially routed through the top 106 or walls 110 of the chamber body 102 to thermally condition the gases.

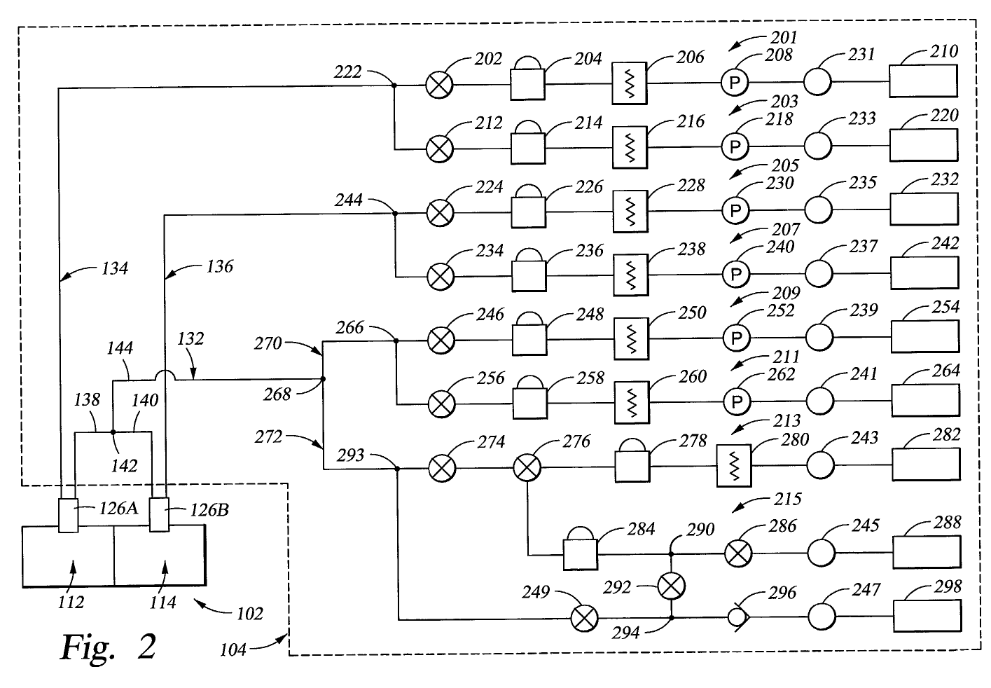

FIG. 2 depicts a flow diagram of one embodiment of the gas distribution system 104. The gas distribution system 104 generally couples at least a first process gas to the processing regions 112, 114 via the first gas supply circuit 132, and couples other process gases to the process regions via gas supply circuits coupled between a single gas source and each processing region 112, 114 on individual circuits, i.e., the second gas supply circuit 134 and the third gas supply circuit 136 depicted in the illustrated gas distribution system 104 of FIG. 2. Other circuits may be utilized in systems having additional chambers and/or process gases. Additionally, as the individual circuits allow independent flow control to the individual processing regions, the individual circuit may share one or more gas sources as long as individual flow control is provided by each circuit.

The gas distribution system 104 generally supplies a first process gas regulated by a first control system 215 from a first process gas source 288, a second process gas regulated by a second control system 201 from a second process gas source 210, a third process gas regulated by a third control system 205 from a third process gas source 232, and an optional fourth process gas regulated by a fourth control system 209 from a fourth process gas source 254. The first process gas is generally supplied to the processing regions 112, 114 with a first carrier gas. The first carrier gas is supplied from a first carrier gas source 282 and regulated by a fifth control system 213. The second process gas is generally supplied to the processing region 112 with a second carrier gas. The second carrier gas is supplied from a second carrier gas source 220 and regulated by a sixth control system 203. The third process gas is generally supplied to the processing region 114 with a third carrier gas. The third carrier gas is supplied from a third carrier gas source 242 and regulated by a seventh control system 207. The optional fourth process gas is generally supplied to the processing region 112 with a fourth carrier gas. The fourth carrier gas is supplied from an fourth gas source 264 and regulated by an eighth control system 211.

The first gas supply circuit 132 is generally coupled between the first gas box 126A and the second gas box 126B. The main delivery line 144 generally is coupled to the first process gas source 254. The first process gas source 254 may be configured to supply any number of process gases dependent upon the desired process to be performed within the processing region. In one embodiment, the first process gas is titanium tetrachloride (TiCl₄).

The first flow control system 215 is fluidly coupled to the main delivery line 144 to control the flow and flow rate and of the first process gas from the first process gas source 288. In one embodiment, the first flow control system 215 generally includes a first flow control system valve 274, an injector valve 276, a first flow control system controller 284, and a first flow control system regulator 245. The valve 274 is generally a shut-off valve of the type typically utilized in cryogenic applications and disposed in the first gas supply circuit 132 between the tee 142 and the first process gas source 288. The valve 274 is generally interlocked with other valves of the system 100 such that inadvertent flow from the first process gas source 288 may be avoided.

The injector valve 276 is coupled between the first flow control system valve 274 and the first process gas source 288. The injector valve 276 generally allows a first carrier gas to be combined with the first process gas prior to the first valve 274. One injector valve which may be utilized is available from HoribaSTEC Corporation.

The first flow control system controller 284 generally controls the flow rate of the first process gas through the first gas supply circuit 132 and is coupled between the injector valve 276 and the first process gas source 288. The first flow controller 284 may be an orifice, mass flow controller, needle valve, proportional valve or other flow regulating device.

The first flow control system regulator 245 regulates the pressure of the first process gas exiting the first gas source 288. The regulator 245 is typically coupled between the controller 284 and the first process gas source 288. Such regulators are generally available from Veriflo Corporation, located in Richmond, Calif.

Generally, the first process gas is introduced into the processing regions 112, 114 with a carrier gas. In the embodiment depicted in FIG. 2, a first carrier gas, such as helium, flowing from the first carrier gas source 282 is coupled to the first flow control system 215 at the injector valve 276. Generally, the flow and flow rate of the first carrier gas is regulated by the fifth flow control system 213.

The fifth flow control system 213 typically comprises a fifth flow control system controller 278, a fifth flow control system filter 280 and a fifth flow control system regulator 243. The controller 278 is generally coupled between the injector valve 276 and the filter 280. The fifth flow control system filter 280 is generally a sub-micron filter utilized to minimize particulates entrained in the first process gas and is coupled between the controller 278 and the regulator 243. Such filters are generally available from Pall Corporation, East Hills, N.Y. The fifth system regulator 243 is generally coupled between the filter 280 and the first carrier gas source 282. The controller 278 and regulator 243 are generally similar to the controller and regulator of the first flow control system 215.

A purge gas source 298 is selectively coupled to the first flow control circuit 132 at a tee 294 which directs a purge gas to a tee 293 disposed between the valve 274 and the tee 142 or to a tee 290 disposed in the first control system 215 between the controller 284 and the pressure regulator 245. A plurality of purge shut-off valves 249, 286 and 292 control the distribution of the purge gas (typically nitrogen) provided by the purge gas source 298. Generally, the purge gas source 298 is selectively coupled to the main delivery line 144 by the purge shut-off valve 249 disposed between the tee 293 and tee 294. The purge gas source 298 is selectively coupled to the first control system 215 by the purge shut-off valve 292 disposed between the tee 290 and tee 294. The purge shut-off valve 286 isolates purge gas within the first control system 215 from the pressure regulator 215.

Generally, the flow of the purge gas is controlled by a purge gas regulator 247 disposed between the purge gas source 298 and the tee 294. A check valve 296 disposed between the tee 294 and the purge gas regulator 298 generally prevents flow towards the purge gas source 298.

The first carrier gas combined with the first process gas at the injector valve 276 and is then introduced into the processing regions 112, 114. In the embodiment depicted in FIG. 2, an optional fourth process gas, for example, chlorine utilized for chamber cleaning, may alternatively be provided at a tee 268 disposed in the first gas supply circuit 132 between the tees 142 and 193. Generally, the flow and flow rate of the fourth process gas is regulated by the fourth flow control system 209.

The fourth flow control system 209 generally includes a fourth flow control system valve 246, a fourth flow control system controller 248, a fourth flow control system filter 250, a fourth flow control system pressure sensor 252 and a fourth flow control system regulator 239. Generally, the valve 246 is coupled between the tee 268 and the controller 248. The filter 250 is coupled between the controller 248 and the pressure sensor 252. The regulator 239 is coupled between the pressure sensor 252 and the fourth gas supply 254.

The fourth flow control system pressure sensor 252 generally provides a controller (not shown) coupled to the system 100 with pressure information utilized to control the flow of the fourth process gas. Such sensors are generally available from MKS Instruments, located in Andover, Mass.

The fourth flow control system valve 246, controller 248 and regulator 239 are generally similar to the valve, controller and regulator of the first flow control system 215. The filter 250 is generally similar to the filter 280 described above.

The fourth process gas is generally delivered to the process regions 112, 114 in the presence of a fourth carrier gas such as nitrogen. The flow of the fourth carrier gas is generally controlled by the eighth flow control system 211 which is coupled to the first gas supply circuit 132 at a tee 266 disposed between the valve 246 and the tee 268.

The eighth flow control system 211 generally includes an eighth flow control system valve 256, an eighth flow control system controller 258, an eighth flow control system filter 260, an eighth flow control system pressure sensor 262 and an eighth flow control system regulator 241. The valve 256 is generally a shut-off valve similar to the valve 274 and is disposed in the first gas supply circuit 132 between the tee 266 and the fourth carrier gas source 264. The valve 256 is generally interlocked with other valves of the system 100 such that inadvertent flow from the fourth carrier gas source 264 may be avoided.

The controller 258 generally controls the flow rate from the fourth carrier gas source 264 and is coupled between the valve 256 and the filter 260. The flow controller 258 is generally similar to the flow controller 284. The filter 260 is generally a sub-micron filter similar to the filter 250. The filter 260 is coupled between the flow controller 258 and the pressure sensor 262.

The pressure sensor 262 generally provides a controller (not shown) coupled to the system 100 with pressure information utilized to control the flow of the fourth carrier gas. The pressure sensor 262 is typically coupled between the filter 260 and the regulator 241.

The regulator 241 regulates the pressure of the fourth carrier gas exiting the fourth carrier gas source 264. The fifth regulator 241 is typically coupled between the pressure sensor 262 and the fourth carrier gas source 264.

The second gas supply circuit 134 provides the second process gas from the second process gas source 210 to the first gas box 126A. A second control system 201 is coupled between the first gas box 126A and the second process gas source 210 to control the flow of the second process gas. The second process gas source 210 may be configured to supply any number of process gases dependent upon the desired process to be performed within the processing region. In one embodiment, the second process gas is ammonia (NH₃).

In one embodiment, the second flow control system 201 generally includes a second flow control system valve 202, a second flow control system controller 204, a second flow control system filter 206, a second flow control system pressure sensor 208 and a second flow control system regulator 231. Generally, the valve 202 is similar to the valve 246 and is coupled between the first gas box 126A and the second process gas source 210. The controller 204 is coupled between the valve 202 and the filter 206. The pressure sensor 208 is generally coupled between the filter 206 and the pressure regulator 231. The pressure regulator 231 is generally coupled between the pressure sensor 208 and the second process gas source 210. The second flow control system controller 204, filter 206, pressure sensor 208 and pressure regulator 231 are generally similar to the controller, filter, pressure sensor and pressure regulators utilized in the first gas supply circuit 132.

Generally, the second process gas is introduced into the processing region 112 with a carrier gas. In the embodiment depicted in FIG. 2, a second carrier gas flowing from the second carrier gas source 220 is coupled to the second flow control system 201 at a tee 222. Generally, the flow and flow rate of the second carrier gas is regulated by a sixth flow control system 203.

The sixth flow control system 203 typically comprises a sixth flow control system valve 212, a sixth flow control system controller 214, a sixth flow control system filter 216, a sixth flow control system pressure sensor 218 and a sixth flow control system regulator 233. The valve 212 is disposed in the third gas supply circuit 136 between the tee 222 and the second carrier gas source 220. The sixth flow control system valve 212 is generally interlocked with other valves of the system 100 such that inadvertent flow from the second carrier gas source 220 may be avoided.

The sixth flow control system controller 214 controls the flow rate from the second carrier gas source 220 and is coupled between the valve 212 and the second carrier gas source 220. The filter 216 is coupled between the controller 214 and the pressure sensor 218. The pressure regulator 233 is generally coupled between the pressure sensor 218 and the second carrier gas source 220. The sixth flow control system valve 212, the controller 214, the filter 216, the pressure sensor 218 and the regulator 233 are generally similar to the controller, filter, pressure sensor and pressure regulators utilized in the first gas supply circuit 132.

The third gas supply circuit 136 provides the third process gas from the third process gas source 232 to the second gas box 126B. The third control system 205 is coupled between the second gas box 126B and the third process gas source 232 to control the flow of the third process gas. The third process gas source 232 may be configured to supply any number of process gases dependent upon the desired process to be performed within the processing region. In one embodiment, the third process gas is ammonia (NH₃).

In one embodiment, the third flow control system 205 generally includes a third flow control system valve 224, a third flow control system controller 226, a third flow control system filter 228, a third flow control system pressure sensor 230 and a third flow control system regulator 235. Generally, the valve 224 is coupled between the second gas box 126B and the third process gas source 232. The controller 226 is coupled between the valve 224 and the filter 228. The pressure sensor 230 is coupled between the regulator 235 and the filter 228. The regulator 235 is generally coupled between the pressure sensor 230 and the third process gas source 232. The third flow control system valve 224, controller 226, filter 228, pressure sensor 230 and pressure regulator 235 are generally similar to the valve, controller, filter, pressure sensor and pressure regulators utilized in the first gas supply circuit 132.

Generally, the third process gas is introduced into the processing region 114 with a carrier gas. In the embodiment depicted in FIG. 2, a third carrier gas flowing from the third carrier gas source 242 is coupled to the third flow control system 205 at a tee 244. Generally, the flow and flow rate of the third carrier gas is regulated by a seventh flow control system 207.

The seventh flow control system 207 typically comprises a seventh flow control system valve 234, a seventh flow control system controller 236, a seventh flow control system filter 238, a seventh flow control system pressure sensor 240 and a seventh flow control system regulator 237. The valve 234 is disposed in the third gas supply circuit 136 between the tee 244 and the third carrier gas source 242. The valve 234 is generally interlocked with other valves of the system 100 such that inadvertent flow from the third carrier gas source 242 may be avoided.

The seventh flow control system controller 236 generally controls the flow rate from the third carrier gas source 242 and is coupled between the valve 234 and flow controller 236. The filter 238 is coupled between the controller 236 and the pressure sensor 240. The pressure regulator 237 is generally coupled between the pressure sensor 240 and the third carrier gas source 242. The seventh flow control system valve 234, the controller 236, the filter 238, the pressure sensor 240 and the regulator 237 are generally similar to the controller, filter, pressure sensor and pressure regulators utilized in the first gas supply circuit 132.

Referring to FIGS. 1 and 2, in one mode of operation, the first gas supply circuit 132 provides about 5 to about 120 sccm of the first process gas (e.g., titanium tetrachloride) through the main supply line 144 which is split at the tee 142 to each gas box 126A, 126B of the processing regions 112, 114. The second gas supply circuit 134 provides about 50 to about 500 sccm of the second process gas (e.g., ammonia) to the first gas box 126A of the processing region 112. Simultaneously, the third gas supply circuit 136 provides about 50 to about 500 sccm of the second process gas (e.g., ammonia) to the second gas box 126B of the processing region 114. The process gases combine and thermally decompose to deposit titanium nitride on the substrate's surface. Depending on the relative deposition results between the processing regions 112 and 114, at least one of the flow rates of the gases flowing the second gas supply circuit 134 and the third gas supply circuit 136 may be adjusted to tune the results so that the substrates processed within the regions 112, 114 yield substantially identical results. As such, the flows of the second and third process gases may be identical or different depending upon the process characteristics of each processing region 112, 114 and the flow circuits coupled thereto. One skilled in the art will recognize that the tuning of multiple process regions may be practiced utilizing deferent deposition or etch processes, different process gases, common gas sources, different processing region configurations and so on.

While the foregoing is directed to the preferred embodiment of the present invention, other and further embodiments of the invention may be devised without departing from the basic scope thereof. The scope of the invention is determined by the claims which follow.

What is claimed is:

1. A substrate processing apparatus, comprising:
one or more chamber bodies defining at least a first processing region and a second processing region therein; and
a gas distribution system coupled to the processing regions, comprising:
a first gas supply circuit coupled between the first processing region and the second processing region and adapted to supply a first process gas thereto;
a second gas supply circuit coupled to first processing region and adapted to supply a second process gas thereto; and
a third gas supply circuit coupled to second processing region and adapted to supply a third process gas thereto.

2. The apparatus of claim 1, wherein the second process gas and the third process gas comprises identical process gas.

3. The apparatus of claim 1, wherein a flow rate of the second process gas is independently controllable relative to the third process gas.

4. The apparatus of claim 1, wherein a flow rate of the second process gas is substantially equal to the third process gas.

5. The apparatus of claim 1, wherein a flow rate of the second process gas is regulated relative to a flow rate of the third process gas to tune deposition results in the first and second processing regions.

6. The apparatus of claim 1, wherein the first gas circuit further comprises:
a first chamber branch coupled to the first processing region;
a second chamber branch circuit coupled to the second processing region;
a tee connecting the first chamber branch and the second chamber branch; and
a flow control system coupled to the tee.

7. The apparatus of claim 6, wherein the flow control system further comprises:
a regulator coupled to a first process gas source; and
a flow controller coupled to the regulator.

8. The apparatus of claim 7, wherein the flow control system further comprises:
a pressure transducer adapted to sense pressure between the regulator and the flow controller; and
a filter disposed between the regulator and the flow controller.

9. The apparatus of claim 7, wherein the first gas circuit further comprises:
a first shut off valve disposed between the first processing region and the flow control system; and
a pressure sensor disposed between the first shut off valve and the first processing region.

10. The apparatus of claim 7, wherein the flow controller further comprises:
an orifice, a mass flow controller, a needle valve or a proportional valve.

11. The apparatus of claim 1, wherein the first gas supply circuit further comprises:
a first process gas delivery branch having the first process gas source fluidly coupled a first carrier gas source;
a second gas delivery branch having a fourth process gas source fluidly coupled a second carrier gas source; and
a least one valve coupled to the first gas delivery branch and/or second gas delivery branch for selectively coupling either the first process gas source or the second process gas source to the first and second processing regions.

12. The apparatus of claim 11, wherein the first process gas comprises titanium tetrachloride and the fourth process gas comprises chlorine.

13. The apparatus of claim 12, wherein the first process gas comprises titanium tetrachloride and/or chlorine, the second process gas comprises ammonia and the third process gas source comprises ammonia.

14. The apparatus of claim 1, wherein the one or more chamber bodies comprise a single chamber body having a top, bottom and sidewalls, at least one interior wall is coupled between the top and bottom, the interior wall separating the first processing from the second processing region.

15. A substrate processing apparatus, comprising:
a chamber body having a top, bottom and sidewalls, at least one interior wall coupled between the top and bottom and defining at least a first processing region and a second processing region within the chamber body; and
a gas distribution system coupled to the chamber body, comprising:
a first gas supply circuit coupled between the first processing region and the second processing region, the first gas supply circuit having at least a first flow controller adapted to selectively supply a first process gas and a fourth process gas to the first and second processing region;
a second gas supply circuit coupled to first processing region and having a second flow controller adapted to supply a second process gas to the first processing region at a first rate; and
a third gas supply circuit coupled to second processing region and having a third flow controller adapted to supply a third process gas to the second processing region at a second rate controlled independently from the first rate to tune deposition results between the first and the second processing region.

16. The apparatus of claim 15, wherein the second process gas and the third process gas comprises identical process gas.

17. The apparatus of claim 15, wherein the first gas circuit further comprises:
a first branch circuit coupled to the first processing region;
a second branch circuit coupled to the second processing region;
a tee connecting the first branch circuit and the second branch circuit; and
a flow control system having the flow controller disposed therein fluidly coupled to the tee.

18. The apparatus of claim 17, wherein the flow control system further comprises:
a regulator coupled between a first process gas source and the first flow controller;
a pressure transducer adapted to sense pressure between the regulator and the first flow controller; and
a filter disposed between the regulator and the first flow controller.

19. The apparatus of claim 15, wherein the flow controller further comprises:
an orifice, a mass flow controller, a needle valve or a proportional valve.

20. The apparatus of claim 15, wherein the first gas supply circuit further comprises:
a first process gas delivery branch having the first process gas source fluidly coupled a first carrier gas source;
a second gas delivery branch having a fourth process gas source fluidly coupled a second carrier gas source; and
a least one valve coupled to the first gas delivery branch and/or second gas delivery branch for selectively coupling either the first process gas source or the second process gas source to the first and second processing regions.

21. The apparatus of claim 15, wherein the first process gas comprises titanium tetrachloride and the fourth process gas comprises chlorine.

22. The apparatus of claim 15, wherein the first process gas comprises titanium tetrachloride and/or chlorine, the second process gas comprises ammonia and the third process gas source comprises ammonia.

23. The apparatus of claim 15, wherein the first and second flow rates are equal.

24. A substrate processing apparatus, comprising:
a chamber body having a top, bottom and sidewalls, at least one interior wall coupled between the top and bottom and defining at least a first processing region and a second processing region within the chamber body; and
a gas distribution system coupled to the chamber body, comprising:
a first gas supply circuit having a tee fluidly coupling the first processing region and the second processing region, a main delivery line having a first process gas delivery branch and a second gas delivery branch selectively coupled to the tee, the first gas delivery branch having a first process gas source and the second gas delivery branch having a second process gas source;
a second gas supply circuit coupled to the first processing region and having a first flow controller adapted to supply a third process gas to the first processing region at a first rate; and
a third gas supply circuit coupled to the second processing region and having a second flow controller adapted to supply a fourth process gas comprising the identical process gas as the third process gas to the second processing region at a second rate controlled independently from the first rate to tune deposition results between the first and second processing regions.

25. The apparatus of claim 24, wherein the second gas supply circuit further comprises:
a regulator coupled between a third process gas source and the first flow controller;
a pressure transducer adapted to sense pressure between the regulator and the first flow controller;
a filter disposed between the regulator and the third flow controller; and
wherein the third gas supply circuit further comprises.
a regulator coupled between a fourth process gas source and the second flow controller;
a pressure transducer adapted to sense pressure between the regulator and the second flow controller; and
a filter disposed between the regulator and the second flow controller.

26. The apparatus of claim 24, wherein the first and second flow controller further comprises:
an orifice, a mass flow controller, a needle valve or a proportional valve.

27. The apparatus of claim 24, wherein the first process gas comprises titanium tetrachloride, the second process gas comprises chlorine, the third process gas comprises ammonia and the fourth process gas source comprises ammonia.

28. A method for processing a plurality of substrates, comprising:
flowing a first process gas to a first process region and a second process region through a common conduit coupled therebetween;
flowing a second process gas to the first process region at a first rate; and
flowing a third process gas to the second process region at a second rate, wherein the first rate and the second rate are independently controlled to tune processing results between the first process region and the second process region.

29. A method for processing a plurality of substrates, comprising:
flowing a first process gas to a first chemical vapor deposition region and a second chemical vapor deposition region through a common conduit coupled therebetween;
flowing a second process gas to the first chemical vapor deposition region at a first rate; and
flowing a third process gas that is the same as the second process gas to the second chemical vapor deposition region at a second rate, wherein the first rate and the second rate are independently controlled to tune deposition results between the first process region and the second process region.

30. The method of claim 29, wherein the second rate is different than the first rate.

31. The method of claim 29 further comprising forming a plasma in the first chemical vapor deposition region from a mixture of the first process gas and the second process gas.

32. The method of claim 29, wherein the first process gas is TiCl₄, and the second and third process gases are NH₃.
